(19) United States
(12) Patent Application Publication
(10) Pub. No.: US 2026/0289045 A1
(43) Pub. Date: Sep. 24, 2026

(54) SYSTEMS AND METHODS FOR REGULARIZATION OF SEISMIC MIGRATION USING A GENERATIVE DIFFUSION MODEL

(71) Applicant: SAUDI ARABIAN OIL COMPANY, Dhahran (SA)

(72) Inventor: Bingbing SUN, Dhahran (SA)

(73) Assignee: SAUDI ARABIAN OIL COMPANY, Dhahran (SA)

(21) Appl. No.: 19/085,964

(22) Filed: Mar. 20, 2025

(51) Int. Cl. G06F 30/27; G06N 3/08

(52) U.S. Cl. CPC G06F 30/27; G06N 3/08

(57) ABSTRACT

This disclosure provides methods for regularization of seismic migration using generative diffusion modelling (GDM) and systems for performing the same. For example, methods may include constructing one or more denoising diffusion probabilistic models based on seismic information. Methods may include training a neural network based on the one or more denoising diffusion probabilistic models (DDPMs) and the loss function of an evidence lower bound (ELBO). Methods may include applying the neural network to a reflectivity profile constructed using the seismic information to construct at least one refined seismic representation. Applying the neural network to the reflectivity profile may regularizing a first iterative portion of the reflectivity profile using the neural network, updating the reflectivity profile based on a learning rate value, and regularizing a second iterative portion of the reflectivity profile using the neural network.

### BACKGROUND

Current seismic migration processes, such as least square migration (LSM), face several challenges that can impact the accuracy and reliability of subsurface imaging. These challenges include the presence of noise and artifacts in the seismic data, which can obscure true geological features and complicate interpretation. Additionally, the complex and heterogeneous nature of subsurface structures can lead to multiple reflections and refractions, making it difficult to accurately image the subsurface. Traditional regularization methods, which often rely on simplified priors, may not be sufficient to handle the complexity of real-world geological formations, leading to oversimplified models. Furthermore, the computational intensity of seismic migration processes can result in significant resource consumption and longer processing times, limiting the scalability and efficiency of these techniques.

Despite advancements in seismic migration techniques, current methods may still be ineffective to achieve optimal results. Accordingly, there is an impetus to improve migration techniques to overcome existing technological challenges by implementing enhancements such as: increasing the reliability of subsurface imaging, reducing inefficiencies associated with the migration process, minimizing the impact of noise and artifacts, decreasing the reliance on simplified priors, improving the accuracy of automated solutions, and the like.

Consequently, further improvements to seismic migration processes may address the aforementioned technical challenges and other challenges not mentioned.

### BRIEF SUMMARY

Various details of the present disclosure are hereinafter summarized to provide a basic understanding. This summary is not an exhaustive overview of the disclosure and is neither in-tended to identify certain elements of the disclosure, nor to delineate the scope thereof. Rather, the primary purpose of this summary is to present some concepts of the disclosure in a simplified form prior to the more detailed description that is presented hereinafter.

According to an aspect of the present disclosure, a system for seismic processing is provided. The system may include a memory. The system may further include one or more processors and coupled to the memory, the memory having computer-readable code stored thereon configured to cause the one or more processors to perform one or more steps. The one or more steps may include constructing, via the one or more processors, one or more denoising diffusion probabilistic models based on seismic information. The one or more steps may include training, via a machine learning engine, a neural network based on the one or more denoising diffusion probabilistic models and an evidence lower bound. The one or more steps may include applying the neural network to a reflectivity profile constructed using the seismic information to construct at least one refined seismic representation. Applying the neural network may include regularizing a first iterative portion of the reflectivity profile using the neural network. Applying the neural network may include updating the reflectivity profile based on a learning rate value. Applying the neural network may include regularizing a second iterative portion of the reflectivity profile using the neural network.

In another aspect, a system for seismic processing is provided. The method may further include one or more steps. The one or more steps may include constructing, via the one or more processors, one or more denoising diffusion probabilistic models based on seismic information. The one or more steps may include training, via a machine learning engine, a neural network based on the one or more denoising diffusion probabilistic models and an evidence lower bound. The one or more steps may include applying the neural network to a reflectivity profile constructed using the seismic information to construct at least one refined seismic representation. Applying the neural network may include regularizing a first iterative portion of the reflectivity profile using the neural network. Applying the neural network may include updating the reflectivity profile based on a learning rate value. Applying the neural network may include regularizing a second iterative portion of the reflectivity profile using the neural network.

Other aspects of the present disclosure provide: one or more devices (e.g., apparatuses) operable, configured, or otherwise adapted to perform the aforementioned methods as well as those described elsewhere herein; a non-transitory, computer-readable media including computer-executable instructions that, when executed by a processor of an apparatus, cause the apparatus to perform the aforementioned methods as well as those described elsewhere herein; a computer program product embodied on a computer-readable storage medium comprising code for performing the aforementioned methods as well as those described elsewhere herein; and an apparatus including means for performing the aforementioned methods as well as those described elsewhere herein. By way of example, an apparatus may include a processing system, or processing systems cooperating over one or more message passing interfaces.

Any combinations of the various embodiments and implementations disclosed herein can be used in a further embodiment, consistent with the disclosure. These and other aspects and features can be appreciated from the following description of certain embodiments presented herein in accordance with the disclosure and the accompanying drawings and claims.

### BRIEF DESCRIPTION OF THE SEVERAL VIEWS OF THE DRAWINGS

Embodiments of the present disclosure will now be described in detail with reference to the accompanying drawing figures. Like elements in the various figures may be denoted by like reference numerals. Further, in the following detailed description, specific details are set forth in order to provide a more thorough understanding of the claimed subject matter. However, it will be apparent to one of ordinary skill in the art that the embodiments disclosed herein may be practiced without these specific details, or with details that are not described herein in the interest of clarity. Thus in some instances, well-known features have not been described in detail to avoid unnecessarily complicating the description. Additionally, it will be apparent to one of ordinary skill in the art that the scale of the elements presented in the accompanying drawing figures may vary without departing from the scope of the present disclosure.

FIG. 1 illustrates an enhanced regularization architecture for implementing methods provided herein, according to at least one aspect of the present disclosure.

FIG. 2 illustrates an example tiled imaged produced by a neural network performing regularization during seismic migration, according to at least one aspect of the present disclosure.

FIG. 3 illustrates an example reflectivity profile constructed in accordance with known methods.

FIG. 4 illustrates an example reflectivity profile constructed in accordance with methods provided herein, according to at least one aspect of the present disclosure.

FIG. 5 is a schematic flowchart of an example method for implementing enhanced regularization by one or more processors, according to at least one embodiment of the present disclosure.

FIG. 6 illustrates a schematic diagram of an example system, according to at least one embodiment of the present disclosure.

FIG. 7 is an example of a block diagram of a system, according to at least one embodiment of the present disclosure.

FIG. 8 depicts a cloud computing environment that can be used to perform one or more actions according to an aspect of the present disclosure.

FIG. 9 is a block diagram of a computer system that may be used to implement one or more of the systems or methods described herein in accordance with certain embodiments.

### DETAILED DESCRIPTION

Aspects of the present disclosure will now be described in detail with reference to the accompanying drawing figures. Like elements in the various figures may be denoted by like reference numerals. Further, in the following detailed description, specific details are set forth in order to provide a more thorough understanding of the claimed subject matter. However, it will be apparent to one of ordinary skill in the art that the aspects disclosed herein may be practiced without these specific details, or with details that are not described herein in the interest of clarity. Thus, in some instances, well-known features have not been described in detail to avoid unnecessarily complicating the description. Additionally, it will be apparent to one of ordinary skill in the art that the scale of the elements presented in the accompanying drawing figures may vary without departing from the scope of the present disclosure.

Aspects in accordance with the present disclosure generally relate to subsurface modeling techniques, and more particularly to systems and methods for enhancing least square migration (LSM) using integrated generative diffusion models.

Disclosed herein are systems and methods to improve the regularization of LSM, an important step to converging a realistic subsurface model. Traditional regularization techniques, such as total variation (TV) regularization, Tikhonov regularization, and L1 (sparse) regularization are typically hand-crafted and based on simplified priors derived from first principles. These conventional methods assume that the ideal subsurface model maintains certain patterns, often leading to oversimplification. To achieve more realistic regularization in LSM, the present disclosure utilizes denoising diffusion probabilistic models (DDPMs) as a prior to stabilize the inversion process.

For example, the systems and methods described herein may combine the loss function of an LSM (e.g., as the standard data fitting term) and an additional regularization term for the image (e.g., reflectivity), framed within the Bayesian variational framework. The additional regularization term may cure model oversimplification by avoiding propagation of artificial patterns throughout the subsurface models subject to migration procedures. In some cases, the additional regularization term may be considered the negative of the evidence lower bound (ELBO). Preliminary results of implementing the systems and methods provided herein demonstrate the effectiveness and robustness of the proposed regularization methods to produced refined subsurface models.

### Example Seismic Migration and Seismic Inversion

In general, seismic migration may begin with the acquisition of raw seismic data, typically gathered through the use of seismic sources and receivers deployed in the field. This data may be in the form of time records that capture the reflections of seismic waves off subsurface structures. The first step in processing this data involves preprocessing, which includes de-noising to remove unwanted signals and de-multiplexing to separate the data into individual traces. Following preprocessing, the data may be subjected to velocity analysis to build a velocity model of the subsurface. A velocity model is constructed to represent varying seismic wave velocities within the subsurface layers of a geological formation subject to evaluation. The process of constructing a velocity model begins with velocity analysis, where velocity values are picked from seismic data at various locations and depths. These values are used to create an initial velocity model through methods such as semblance analysis or tomography. The model is iteratively refined by comparing predicted seismic data with actual data, adjusting the velocity values to minimize discrepancies. The velocity model is used to guide migration algorithms, ensuring that seismic reflections are correctly positioned in their true subsurface locations. Accurate velocity models are essential for producing high-quality migrated seismic images that correctly reflect the subsurface geology.

The general workflow of complex mathematical computations for migration may involve several steps. Initially, preprocessed seismic data and the constructed velocity model are input into the migration algorithm. Methods such as Kirchhoff migration, finite-difference migration, and reverse time migration (RTM) may be used. Kirchhoff migration sums seismic data along diffraction curves defined by the velocity model, while finite-difference migration solves the wave equation numerically to extrapolate the seismic wavefield backward in time. RTM uses the full wave equation to migrate data, providing high accuracy for complex geological settings. These algorithms involve intensive computations, often requiring high-performance computing resources. The output is a migrated seismic image where seismic events are repositioned to their correct spatial locations, providing a clearer and more accurate representation of subsurface structures.

Seismic inversion takes the migrated seismic image as its starting point and aims to derive quantitative rock property information from it. The first step in this process may be the extraction of seismic attributes, which involves analyzing the seismic data to obtain parameters such as amplitude, phase, and frequency. Seismic attributes are quantitative measures derived from seismic data that provide additional information about the subsurface. The extraction process begins with analyzing the migrated seismic image to obtain basic attributes such as amplitude, phase, and frequency. Advanced attributes, such as instantaneous amplitude, instantaneous phase, instantaneous frequency, coherence, curvature, and spectral decomposition can also be derived. The extraction process may involve various signal processing techniques to ensure that the attributes are accurately computed and validated against known subsurface conditions.

Seismic inversion may involve several steps. Initially, extracted seismic attributes and the migrated seismic image may be used as inputs. The first step is selecting an appropriate inversion method, such as deterministic inversion, which aims to produce a single best-fit model, or stochastic inversion, which generates multiple realizations to quantify uncertainty. The inversion process begins with constructing an initial model based on prior geological knowledge and well data. The inversion algorithm iteratively adjusts the model parameters to minimize the difference between observed seismic data and synthetic data generated by the model. This is achieved through optimization techniques such as least-square migration (LSM) or Bayesian inference. The final output is a set of rock property models, such as acoustic impedance, porosity, and fluid content, providing detailed insights into the subsurface. These models are used for further geological and reservoir characterization, aiding in decision-making processes for exploration and production. The qualitative impact of a preceding migration process may be significant, as the quality of the migrated seismic image directly affects inversion results. If the migration process has flaws, the resulting seismic image may be inaccurate, potentially leading to less reliable inversion outcomes. Therefore, ensuring a robust migration process may be considered essential for achieving reliable and precise subsurface property estimations during inversion.

### Example Regularization of Least-Square Migration

Least-square migration (LSM) is an advanced seismic migration method that aims to produce high-resolution subsurface images, which are crucial in the exploration of natural resources like oil and gas.

The principle behind LSM is rooted in the least square method, a optimization technique that minimizes the sum of the square differences between observed (or measured) and predicted data. In the context of LSM, the observed data is the seismic data recorded on the surface or within a borehole, and the predicted is the seismic response calculated from an initial model of the subsurface using an approximated wave propagating physics model. The LSM process iteratively updates this initial model to reduce the difference between the observed and predicted data. This is achieved by solving a large-scale inversion problem, which can yield more accurate and higher resolution images of the subsurface compared to conventional migration methods.

During implementation of LSM techniques, noise and oversimplified regularization methods can hinder the convergence to a realistic subsurface model. Due to both noise in the raw seismic data and the inherent limitations of the seismic data acquisition, regularization is essential for a successful application of the LSM for field dataset. Regularization techniques stabilize the inversion process, prevent model overfitting, mitigate the effects of noise and non-uniqueness, and address and clean incomplete data sets. Robust regularization is often difficult to implement, as subsurface geologies often possess complex heterogeneity; however, robust regularization may result in more accurate and high-resolution models of subsurface properties such as acoustic impedance, velocity, and density, thereby enhancing data interpretability and providing detailed representations of subsurface structures essential for hydrocarbon exploration and reservoir characterization.

Regularization may refer to the incorporation of prior information to adjust model parameterization. Conventional regularization methods for LSM typically use simplified priors to perform regularization. In areas with complex geology (e.g., unconventional reservoirs), such simplified priors are often inadequate, and more realistic priors are preferred.

### Aspects Related to Regularization of Seismic Migration Using a Generative Diffusion Model

In certain cases, generative diffusion models (GDMs) may be useful for regularization of generalize statistical models. GDMs are a type of deep-learning, generative machine learning model that can construct a representative diffusion process to generate new data samples. GDM techniques may start with a simple distribution, like Gaussian noise, and gradually transform it into a complex data distribution, such as images or text, through a series of small diffusion steps. Unlike other generative models, GDMs may simulate a diffusion process that starts with a simple distribution, such as Gaussian noise, and gradually transforms it into a complex data distribution through a series of small, iterative steps. This approach allows GDMs to capture intricate patterns and structures in the data.

Aspects of the present disclosure provide a method and system to regularize LSM using one of more GDMs as a source for prior information. Methods and systems provided herein, byway of the GDMSs, may improve the efficiency of seismic migration procedure and may improve the fidelity of seismic inversion procedures.

One or GDMs presented according to aspects of the present disclosure is their ability to learn and represent complex distributions with high fidelity. This capability makes them particularly well-suited as priors for inverse problems, where the goal is to infer underlying parameters or structures from observed data. In the context of LSM, using GDMs as a prior can significantly enhance the regularization process. By incorporating the rich, learned distributions from GDMs, LSM can achieve more accurate and stable solutions, even in the presence of noise and other uncertainties.

In at least one aspect of the present disclosure, a denoising diffusion probabilistic model (DDPMs) is used as a GDM during LSM migration regularization, though other GDMs are contemplated within the scope of the disclosure. DDPMs may include two Markov processes. The first process may be considered a forward process and the second may be considered backwards process. The forward process may be a fixed diffusion process where the original data is gradually corrupted by adding Gaussian noise until it becomes completely random. Conversely, in the reverse process, the model (e.g., implemented by a neural network) may learn to reverse this process, staring form the noisy data and progressively removing the noise to recover the original data.

Additional information regarding the DDPM forward and backwards processes are provided herein. It should be understood that any equation (e.g., Equations [1]-[15]) provided herein with respect to the present disclosure is illustrative to describe processor operations by a seismic computer system configured or otherwise arranged to efficiently perform methods provided herein. A dedicated computer system for seismic tasks is necessary to perform seismic migration and inversion. Typically, dedicated computer systems for seismic tasks include high-performance computing (HPC) resources by way of the intensive computational demands of these processes. A dedicated computer system for seismic tasks may include a cluster of interconnected servers, each equipped with multiple high-speed processors (CPUs) or graphics processing units (GPUs) to handle parallel processing tasks efficiently. Parallelization is crucial in this context, as it allows the distribution of complex mathematical computations across multiple processors, significantly reducing processing time and enhancing performance. These processors should have high core counts and fast clock speeds to manage the parallelized tasks involved in migration and inversion algorithms. Additionally, the dedicated computer systems for seismic tasks should have substantial memory, often in the range of about hundreds of gigabytes to terabytes, to store and process large datasets without bottlenecks. High-speed storage solutions, such as solid-state drives (SSDs) or high-performance network-attached storage (NAS), are essential for quick data access and retrieval. The network infrastructure should support high bandwidth and low latency to facilitate rapid data transfer between nodes in the cluster. Finally, robust cooling systems and power supplies are necessary to ensure the hardware operates reliably under the heavy computational loads typical of seismic data processing tasks.

### DDPMs Forward Process:

The forward Markov process q may be defined in Equation [1]:

$$q ( {x}_{1} , {x}_{2} , … , {x}_{T} \vert {x}_{0} ) = {\prod }_{t = 1}^{T} q ( {x}_{t} \vert {x}_{t - 1} ) , \qquad [ 1 ]$$

where T may be considered the total number of steps for diffusion, xᵢ, i=0, . . . , T may be considered a multidimensional array (e.g., such as the reflectivity (the image, the reflector) in least square migration) in different time steps. Specially, xd may be considered the sample from the data distribution (e.g., a realistic prior of the reflectivity in least square migration), while xᵢ may be considered the intermediate samples after incremental diffusion (e.g., adding noise to x₀). The intermediate samples can also be considered as latent variables in the framework of Bayesian variational inference.

At each iteration of the forward process, Gaussian noise may be added according to Equation [2]:

$$q ( {x}_{t} \vert {x}_{t - 1} ) = 𝒩 ( {x}_{t} ; \sqrt{1 - {β}_{t}} {x}_{t - 1} , {β}_{t} I ) , \qquad [ 2 ]$$

where noise schedule parameter βₜ may be considered a scalar value in the range [0,1] and fixed for each time step and I may be considered the identity matrix. With proper defined βₜ, the forward diffusion process tries to reduce the information content and enhance the noise level. To speed up the training, systems and methods provided herein can sample arbitrary time step t without referring to the chain formula as follows:

$$q ( {x}_{t} \vert {x}_{0} ) = 𝒩 ( {x}_{t} , \sqrt{{\tilde{α}}_{t}} {x}_{0} , ( 1 - {\tilde{α}}_{t} ) I ) , \qquad [ 3 ]$$

with αₜ=1−βₜ, and \tilde{α}=Πₛ₌₀^{t}αₛ. With reparameterization, systems and methods provided herein may define an intermediate sample x₀ at time step t as:

$${x}_{t} = \sqrt{{\tilde{α}}_{t}} {x}_{0} + \sqrt{1 - {\tilde{α}}_{t}} ϵ , ϵ ∼ 𝒩 ( 0 , I ) \qquad [ 4 ]$$

The schedule of βₜ usually makes the resulting distribution q(xₜ|x₀) approaches the standard Gaussian distribution [symbol] (x; 0, I). By the reverse process, systems and methods provided herein can generate the data starting from a random signal.

### DDPMs Reverse Process:

Within the realm of machine learning, the reverse process may be structured as a neural network, with parameters denoted by θ:

$${p}_{θ} ( {x}_{0} , {x}_{1} , … , {x}_{T} ) = p ( {x}_{T} ) {\prod }_{t = 1}^{T} {p}_{θ} ( {x}_{i - 1} \vert {x}_{t} ) . \qquad [ 5 ]$$

Similar to forward process, transition in the reverse step may be defined as Gaussian distribution:

$${p}_{θ} ( {x}_{t - 1} \vert {x}_{t} ) = 𝒩 ( {x}_{t - 1} ; {μ}_{θ} ( {x}_{t} , t ) , {Σ}_{θ} ( {x}_{t} , t ) ) . \qquad [ 6 ]$$

Here μ_{θ} and Σ_{θ} are the mean and variance respectively. In DDPMs, the variance part Σ_{θ} may be fixed and not trained, though variations of DDPMs are contemplated in this disclosure.

In at least one embodiment, the DDPM may be trained using a training diffusion model with an evidence lower bound (ELBO) technique:

According to Bayesian variational inference, the loss function for training the DDPMs is given by the evidence lower bound (ELBO), such as provided in Equation [7]:

$$ELBO = {𝔼}_{q ( {x}_{1 : T} \vert {x}_{0} )} [ log \frac{p ( {x}_{T} ) {\prod }_{t = 1}^{T} {p}_{θ} ( {x}_{t - 1} \vert {x}_{t} )}{{\prod }_{t = 1}^{T} {p}_{θ} ( {x}_{t} \vert {x}_{t - 1} )} ] \leq log p ( x ) . \qquad [ 7 ]$$

DDPMs may reparametrize the mean, μ_{θ}, in Equation [6] using the added noise e and simplify the ELBO objective in Equation [7] to be a denoising formula, as follows:

$${Loss}_{ELBO} = {𝔼}_{t , {x}_{0} , ϵ} {‖ ϵ - {ϵ}_{θ} ( {x}_{t} = \sqrt{{\tilde{α}}_{t}} {x}_{0} + ( \sqrt{1 - {\tilde{α}}_{t}} ϵ , t ) ‖}^{2} . \qquad [ 8 ]$$

Intuitively, the reverse process can be perceived as making predictions and fitting the introduced noise, denoted as e. In certain cases, a U-net may be employed for the noise neural network ϵ_{θ}, given its ability to maintain accuracy and efficient performance in pixel-level prediction tasks.

During the DDPMs training process, systems and methods provided herein can perform random sampling of the model x₀, noise e and diffusion time steps t. As implied by its name, DDPMs may learn the data distribution through a denoising process. According to Equation [7], a well-trained DDPMs may result in a smaller loss with respect to Equation [8], indicating a larger ELBO and thus better likelihood, log p (x). Thus, systems and methods provided herein can utilize the denoising objective (e.g., the ELBO) of Equation [8] as a prior for regularization in full waveform inversion. By utilizing the ELBO of Equation [8] as a prior, LMS implemented for inversion may be more accurate to represent certain qualities of a geological formation. High accuracy at the inversion step may ultimately provide higher accuracy for any subsequent seismic interpretation reliant on the inversion step.

In at least one embodiment, LSM is a technique for iteratively updating the image of the subsurface (e.g., during a seismic migration step or a seismic inversion step). It can be applied to post or pre-stack seismic data, in the depth or the time domain, with ray-based (e.g., such as the Kirchhoff migration) or wave equation-based (e.g., one-way migration or reverse time migration) physical modeling. LMS can accommodate different kinds of physical models, such as an acoustic model or an elastic model with or without anisotropy.

In at least one aspect of the present disclosure, LMS time migration is implemented via systems and/or methods provided herein. In a certain aspect, and in the example provided below, LMS migration may be implemented using an acoustic assumption of the physical model. Elastic models and other suitable models are also considered with the scope of this disclosure.

Constant density acoustic waves may be defined according to Equation [9]:

$$\frac{1}{{υ}^{2}} \frac{{\partial }^{2} u}{\partial {t}^{2}} = Δ u + f ( x , t ) , \qquad [ 9 ]$$

where v may be considered the velocity model, u may be considered the pressure wavefield, f(x, t) may be considered the source function, and Delta-u may be considered the Laplacian operator.

Systems and methods provided herein may provide a perturbation of the velocity model v=v₀+δv, where the pressure wavefield is perturbed accordingly, u=u₀+δu. By approximation of Equation [9], the scattering wavefield, Su, may satisfy:

$$\frac{1}{{υ}_{0}^{2}} \frac{{\partial }^{2} δ u}{\partial {t}^{2}} = Δ δ u + \frac{2}{{υ}_{0}^{3}} δ υ \qquad [ 10 ]$$

The background wavefield u₀ satisfies:

$$\frac{1}{{υ}_{0}^{2}} \frac{{\partial }^{2} {u}_{0}}{\partial {t}^{2}} = Δ {u}_{0} + f ( x , t ) \qquad [ 11 ]$$

Equations [10] and [11] are used to forward the construct parameterization used in LSM. Specifically, Equations [10] and [11] build the connection between the scatters, δv (denoted here as “m”) and the scattering wavefield δu (denoted here as “d”). Thus, provided an operator F, by Equation [10] and [11], given the reflectivity (the image) m, systems and methods provided herein can simulate the wavefield d. Where the measured wavefield may be considered d₀, the least square reverse time migration can be formulated as minimization of the following loss function:

$${Loss}_{LSM} = \frac{1}{2} {‖ F ( m ) - {d}_{0} ‖}_{2}^{2} . \qquad [ 12 ]$$

A gradient descent algorithm can be used to solve Equation [12]:

$$m ← m + {η [ \frac{\partial F}{\partial m} ]}^{T} ( F ( m ) - {d}_{0} ) \qquad [ 13 ]$$

where

$${[ \frac{\partial F}{\partial m} ]}^{T}$$

may be considered the adjoint operator of the Forward operator, which can be solved as Equation [10] in reverse time order. In certain aspects, η may be considered the learning rate (e.g., the step for updating the model m).

Systems and methods provided herein may continue updating the reflectivity or the image m, until specified iteration number or accuracy achieved.

Systems and methods provided herein may perform regularization for LSM by ELBO according to the following exemplary equations. To start, the proposed regularization by ELBO using DDPMs for least square reverse time migration is formulated as follows:

$${Loss}_{LSM + DDPMs} = {Loss}_{LSM} + λ {Loss}_{ELBO} = \frac{1}{2} {‖ F ( m ) - {d}_{0} ‖}_{2}^{2} + λ \frac{1}{2} {𝔼}_{t , ϵ} {‖ {ϵ}_{0} ( {m}_{t} = \sqrt{{\tilde{α}}_{t}} m + \sqrt{1 - {\tilde{α}}_{t}} ϵ , t ) - ϵ ‖}_{2}^{2} \qquad [ 14 ]$$

The scalar λ may be used to balance the original LSM data fitting term, denoted as Loss_{LSM} and the regularization term, denoted as LossELBO. In some cases, the neural network ϵ_{θ} may be pre-trained. In other cases, the neural network ϵ_{θ} may be trained in real-time, parallel to generation of a DDPMs prior. In certain cases, only the image (e.g., reflectivity) m is subject to change.

In at least one embodiment, the gradient of Equation may include two terms. The first term may be considered the same as a term in Equation [13], corresponding to the conventional gradient obtained by backpropagating the data residual and the second term corresponds to gradient of the regularization.

$$\frac{\partial {Loss}_{ELBO}}{\partial m} = {𝔼}_{t , ϵ} \{ {[ \frac{\partial {ϵ}_{θ} ( m , t )}{\partial {m}_{t}} ]}^{T} \frac{\partial {m}_{t}}{\partial m} [ {ϵ}_{θ} ( {m}_{t} , t ) - ϵ ] \} \qquad [ 15 ]$$

Updating the reflectivity m follows the same procedure of solving a LSM, such as using gradient descent described before.

The approach provided above with respect to Equations [1]-[14], when implemented on a dedicated computer system for seismic tasks, incorporates a loss function for LSM that includes both the standard data fitting term and an additional regularization term for the image (e.g., reflectivity). By implementing the above approach using systems and methods provided herein, seismic processing workflow may be equipped to accurately handle more complex and realistic patterns in a subsurface formation targeted for seismic interpretation. Specifically, the regularization term, which may be trained to capture accurate heterogeneity of raw seismic data, may act as a prior information constraint to better reflect true geological features, leading to more accurate and stable inversion results.

The following discussion is presented to described systems and methods provided herein, as they implement the approach of Equations [1]-[15].

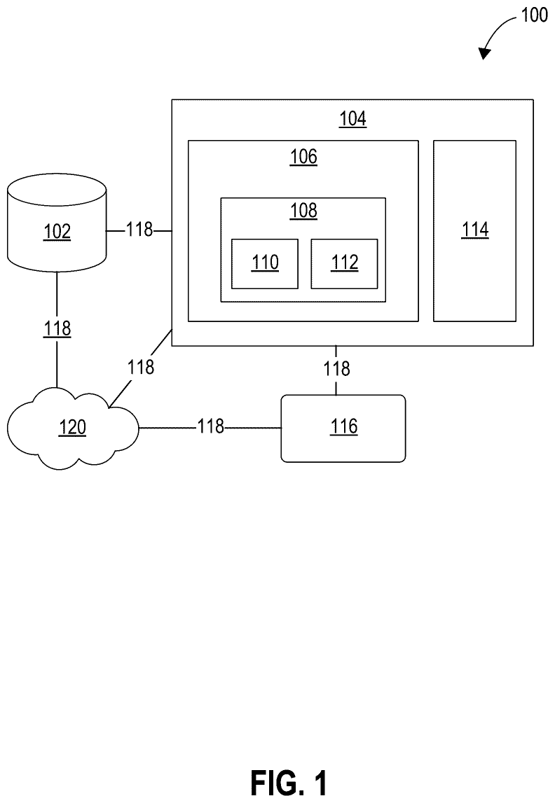

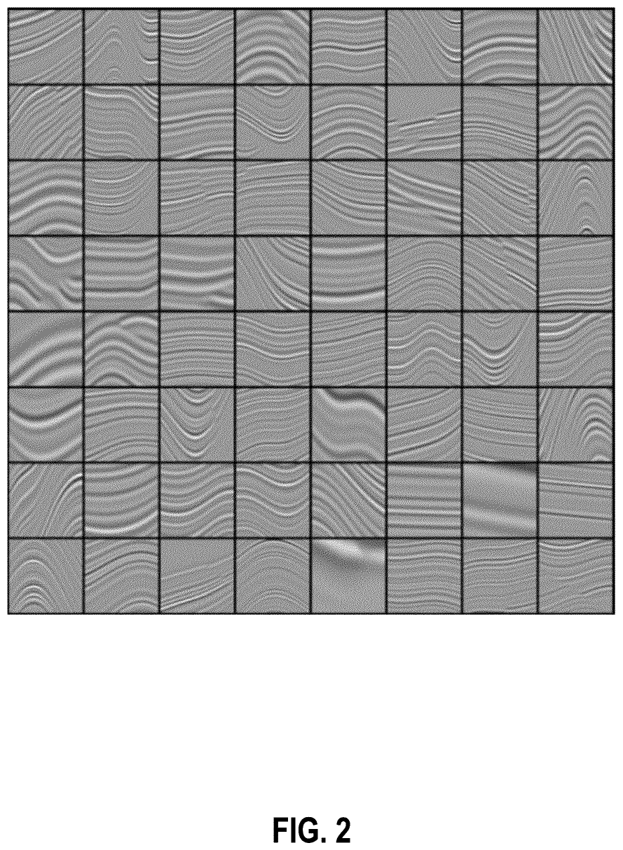

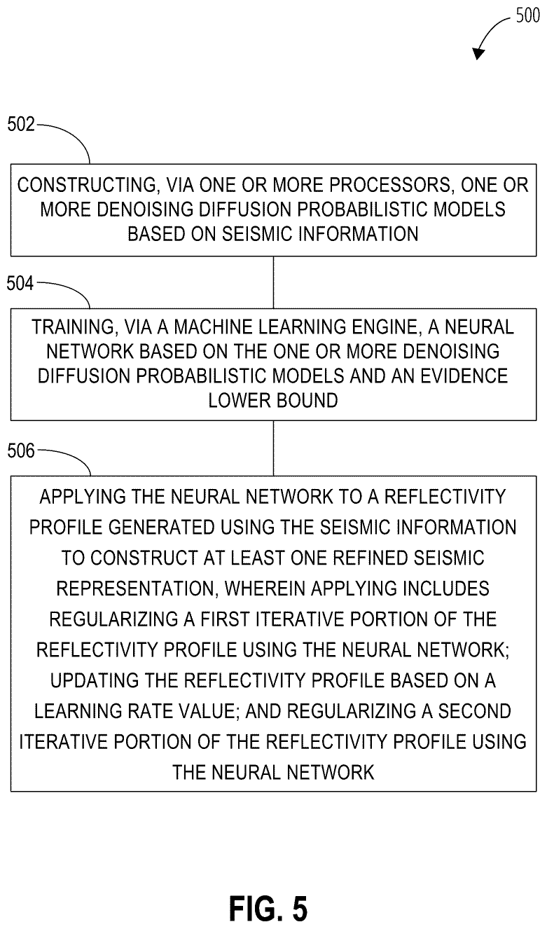

Aspects described herein provide an enhanced regularization architecture (e.g., enhanced regularization architecture 100). In at least one aspect, the enhanced regularization architecture is configured or otherwise arranged to perform methods provided herein (e.g., method 500 of FIG. 5). In at least one aspect, the enhanced regularization architecture is configured or otherwise arranged to process data described in further detail with respect to FIGS. 2-4. Additionally, it may be understood that features of FIGS. 2-9 are inherently and broadly described with respect to the enhanced regularization architecture of FIG. 1.

The illustrative diagram of FIG. 1 provides an example of enhanced regularization architecture 100. Enhanced regularization architecture 100 includes one or more databases 102, one or more units 104, and an output device 116. Unit 104 includes a migration manager 106 and an inversion manager 114, Migration manager 106 includes machine learning engine 108. Machine learning engine 108 is configured to operate a training engine 110 during training and an inference engine 112 during inference. Unit 104 is coupled through communication pathways 118 to database 102 and output device 116. Communication pathways 118 may also couple database 102, unit 104 and output device 116 over a network 120.

In at least one aspect, an example method of regularization begins at the enhanced regularization architecture 100 when one or more processors of one or more units 104 retrieving, from a one or more databases 102 and via network 120, at least one set of seismic information collected over time at a targeted seismic formation. One or more units 104 proceed to constructing, for example via one or more processors operating in parallel, one or more DDPMs based on at least one set of seismic information, wherein constructing comprises. Each DDPM may be understood to be a multidimensional diffusion structure may be understood to be the multidimensional array described with respect to Equation [1]. In some embodiments, the one or more DDPMs may represent image information, such as reflectivity information. One or more units 104 may construct the one or more DDPMs by sampling distribution information derived from the seismic information, supplying noise (e.g., Gaussian noise) to distribution information derived from the seismic information. This process may proceed up to a time step value, as described with respect to Equations [2] and [3]. In some cases, each time step value may be considered intermediate samples of noise and data information. One or more units 104 may implement the intermediate samples as latent variables during the training of the neural network (e.g., by way of Bayesian techniques, see discussion of Equation [4], above).

One or more units 104 may proceed to training, via machine learning engine 108 at one or more units 104, a neural network based on the multidimensional diffusion structure and an ELBO value. This process may be understood with respect to the discussion of Equations [4]-[8], above. Machine learning engine 108 may perform training operations using training engine 110 configured to train the neural network and inference engine 112 configured to apply the neural network to a wavefield of seismic information. Training engine 110 may input, via one or more processors operating in parallel, the multidimensional diffusion structure; and may compare, to a previous output of the neural network, a current outputs of the training engine, wherein comparing is based on at least the first set of noise. Training engine 110 may then proceed to, based on the comparing, adjust one or more weights of the neural network. In some cases, training engine 110 is configured or otherwise arranged to remove noise from the neural network. In some cases, training engine 110 is configured or otherwise arranged to obtain a denoising object by reprioritizing a mean value of one or more DDPMs in relation to at least the removing of the first set of noise (e.g., see Equation [7]). Inference engine 112 may then apply the neural network to a reflectivity profile constructed using the seismic information (e.g., see m of Equations [10]-[14]) to construct at least one refined seismic representation (e.g., a seismic model refined according to procedures represented in Equations [13]-[15]). Application of the neural network may include regularizing a first iterative portion of the reflectivity profile using the neural network (e.g., see at least terms ϵ_{θ}, λ, and LOSS_{ELBO} of Equation [14]), updating the reflectivity profile based on a learning rate value (e.g., see at least η of Equation [13] used to track iterative adjustments to m), and regularizing a second iterative portion of the reflectivity profile using the neural network (e.g., see Equation [15]). The one or more units 104 may then output, via network 120, the at least one refined seismic representation to output device 116.

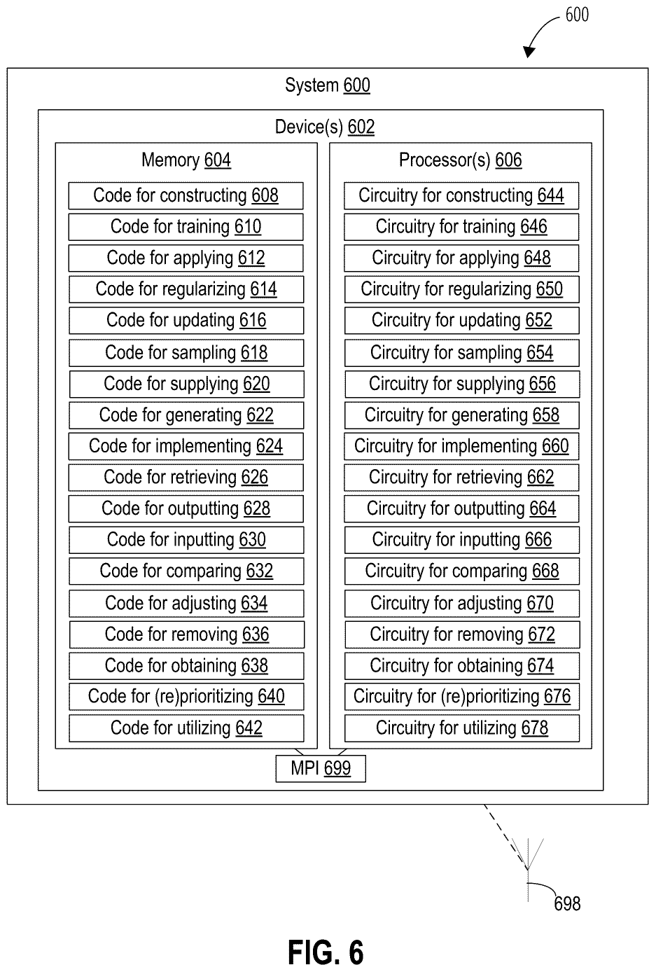

The systems and methods described with respect to FIG. 1 may be further described below with respect to method 500 of FIG. 5 and the system 600 of FIG. 6.

In at least one aspect, each of one or more databases 102, one or more units 104, migration manager 106, machine learning engine 108, training engine 110, inference engine 112, inversion manager 114, and/or output device 116 may be practically implemented as one or more units, one or more databases, and/or one or more devices. In at least one aspect, each of one or more databases 102, one or more units 104, migration manager 106, machine learning engine 108, training engine 110, inference engine 112 inversion manager 114, and/or output device 116 may have at least one memory and one or more processors having computer readable instructions stored thereon, which are capable of implementing enhanced data processing schemes as part of the enhanced regularization architecture 100. In at least one aspect, one or more databases 102, one or more units 104, migration manager 106, machine learning engine 108, training engine 110, inference engine 112 inversion manager 114, and/or output device 116 may have at least one memory and one or more processors having computer readable instructions stored thereon, which are capable of implementing enhanced regularization schemes as part of the function of the enhanced regularization architecture 100. The one or more processor(s) of one or more databases 102, one or more units 104, migration manager 106, machine learning engine 108, training engine 110, inference engine 112 inversion manager 114, and/or output device 116 may be central processing units (CPUs). The one or more processor(s) of unit 102, unit 104, unit 106, and/or unit 108 may be graphics processing units (GPUs). Where there is more than one processor, each processor may operate independently from one another or as part of the same network of controllers and/or systems. Where multiple processors are part of the same network of controllers and/or systems, they may operate in sequence with one another, in parallel with one another, as physical components of a shared virtual machine, or as components of server-less network capable of processing decomposed flow data (e.g., a Kubernetes-based architecture). Where there is more than one processor, each processor may undergo decomposition to perform some or all of a performance of a method, such as method 500 described herein, in order to increase the efficiency of enhanced regularization architecture 100.

In at least one embodiment, one or more databases 102 may include databases configured for storing seismic data. Data types associated with seismic data include SEG-Y files, SEG-D files, SEGDrev3 files, SEGYrev1 files, SEG-Y files, SPS files, UKOOA P2/94 files, UKOOA P6/98 files, HDF5 files, LAS files (e.g., Log ASCII Standard) comma-separated value (CSV) files, and extensible Markup Language (XML) files. Database types may include one or more of relational databases (RDBMS) which use structured query language (SQL) for data management, NoSQL databases (e.g., document stores, key-value stores, column-family stores, graph databases), in-memory databases, NewSQL databases, time-series databases, object-oriented databases, hierarchical databases, network databases, distributed databases, cloud databases, multimodel databases, embedded databases, and the like. One or more databases 102 may be treated as a data warehouse, data lake, data well, or another storage system. One or more databases 102s may be optimized for seismic migration and inversion, allowing the enhanced regularization architecture to perform methods described herein (e.g., method 500).

In at least one aspect, network 120 may be practically implemented as one or more networks. Network 120 may be a wired network, a wireless network, or a combination of both. In at least one aspect, a wireless network may include a wireless local area network (WLANs) (e.g., a wireless fidelity (Wi-Fi) network), a wireless personal area networks (WPANs) (e.g., a Bluetooth network, a Zigbee network), a wireless metropolitan area network (WMANs) (e.g., a worldwide interoperability for microwave access (WiMAX) network), a wireless wide area network (WWANs) (e.g., a fourth generation long-term evolution (4G LTE) network, a fifth generation new radio (5G NR) network, satellite networks, mesh networks, ad hoc networks, near field communication (NFC) networks, infrared (IR) communication networks, ultra-wideband (UWB) networks, long range wide area networks (LoRaWAN) (e.g., a network optimized for Internet-of-Things (IoT) applicability), and the like.

FIGS. 2-4 illustrate example image information generated by the systems and methods provided herein. For instance, FIG. 2 depicts patches generated from a well-trained generative diffusion model (e.g., used to generate a neural network). The high-resolution layered structures may be considered a realistic prior for LSM. These systems and methods can be implemented with predicate seismic acquisition arrangements having sparse sources and receivers.

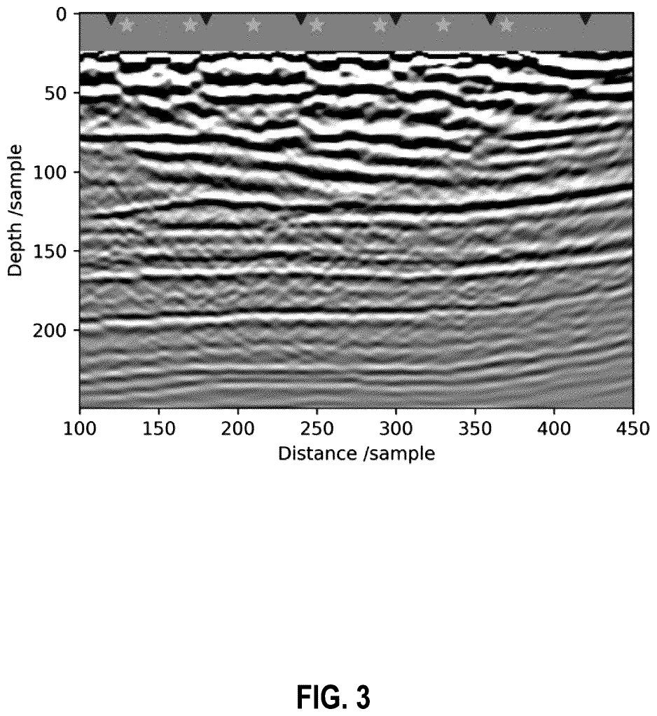

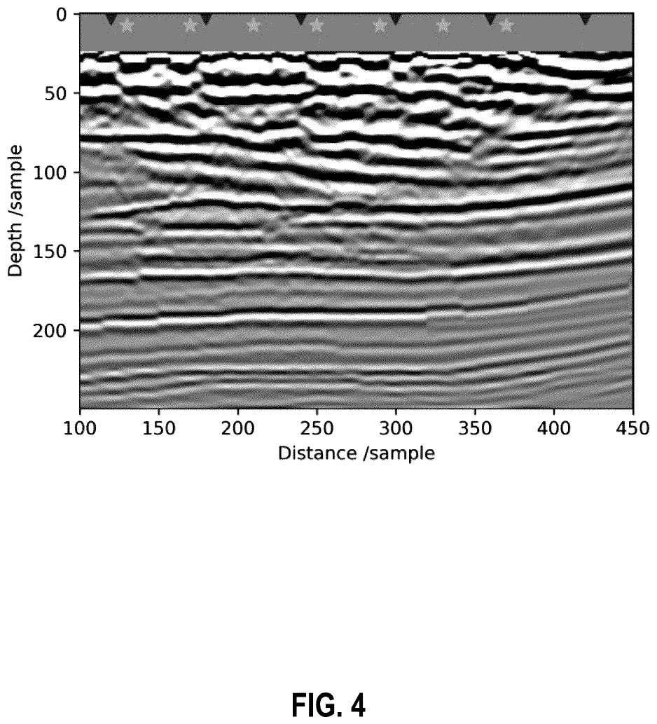

FIGS. 3 and 4 demonstrate the processing differences between a conventional LSM and an LSM enhanced by the systems and methods described herein. Specifically, FIG. 3 shows the result provided by a conventional LSM, which can be contrasted with FIG. 4. FIG. 4 illustrates the result provided by an LSM enriched according to the systems and methods described herein. The regularization provided by the systems and methods in FIG. 4 significantly reduces noise and artifacts, resulting in more continuous and well-defined imaged reflectors, especially in the deeper parts of the representation. The value of the example in FIG. 4 would be evident to a user (e.g., a seismic interpreter), who would be able to use the image in FIG. 4 to more accurately characterize the targeted subsurface formation.

Various embodiments described herein can constitute one or more technical improvements over conventional seismic data processing operations by incorporating advanced regularization techniques using DDPMs. Additionally, one or more embodiments described herein can have a practical application by training machine learning models to perform the seismic inversion operations in accordance with defined geophysical objectives. For example, one or more embodiments described herein can enhance the accuracy and stability of subsurface imaging. Moreover, the machine learning engine can be executed to generate high-resolution layered structures by way of neural networks, which may then serve as part of realistic priors for LSM. Thereby, the seismic data processing engine can apply the neural networks to significantly reduce noise and artifacts, resulting in more continuous and well-defined imaged reflectors, especially in the deeper parts of the subsurface representation.

As used herein, the term “machine learning model” can refer to a computer model used to facilitate one or more machine learning tasks (e.g., regression and/or classification tasks). For example, a machine learning model can represent relationships (e.g., causal or correlation relationships) between parameters and/or outcomes within the context of a specified domain. For instance, machine learning models can represent the relationships via probabilistic determinations that can be adjusted, updated, and/or redefined based on historic data and/or previous executions of a machine learning task. In various aspects described herein, machine learning models can simulate a number of interconnected processing units that can resemble abstract versions of neurons. For example, the processing units can be arranged in a plurality of layers (e.g., one or more input layers, hidden layers, and/or output layers) connected by varying connection strengths (e.g., which can be commonly referred to within the art as “weights”).

Machine learning models can learn through training with one or more training datasets; where data with known outcomes in inputted into the machine learning model, outputs regarding the data are compared to the known outcomes, and/or the weights of the machine learning model are autonomously adjusted based on the comparison to replicate the known outcomes. As the one or more machine learning models train (e.g., utilize more training data), the machine learning models can become increasingly accurate; thus, trained machine learning models can accurately analyze data with unknown outcomes, based on lessons learned from training data and/or previous executions, to facilitate one or more machine learning tasks.

Example types of machine learning models can include, but are not limited to: artificial neural network (“ANN”) models, perceptron (“P”) models, feed forward (“FF”) models, radial basis network (“RBF”) models, deep feed forward (“DFF”) models, recurrent neural network (“RNN”) models, long/short memory (“LSTM”) models, gated recurrent unit (“GRU”) models, auto encoder (“AE”) models, variational AE (“VAE”) models, denoising AE (“DAE”) models, sparse AE (“SAE”) models, markov chain (“MC”) models, Hopfield network (“HN”) models, Boltzmann machine (“BM”) models, deep belief network (“DBN”) models, convolutional neural network (“CNN”) models, deep convolutional network (“DCN”) models, deconvolutional network (“DN”) models, deep convolutional inverse graphics network (“DCIGN”) models, generative adversarial network (“GAN”) models, liquid state machine (“LSM”) models, extreme learning machine (“ELM”) models, echo state network (“ESN”) models, deep residual network (“DRN”) models, kohonen network (“KN”) models, support vector machine (“SVM”) models, and/or neural turing machine (“NTM”) models.

### Example Methods

FIG. 5 is a schematic flowchart of an example method 500 for implementing enhanced regularization by one or more processors, such as the processors of system 600 of FIG. 6.

Method 500 begins at operation 502 with one or more processors constructing, via the one or more processors, one or more denoising diffusion probabilistic models (DDPMs) based on seismic information. In some examples, constructing the DDPMs may include sampling at least a first set of distribution information derived from the seismic information. Constructing the DDPMs may include supplying a first set of noise to at least a second set of distribution information derived from the seismic information. In some examples, constructing the DDPMs may include sampling at least the second set of distribution information. In some examples, constructing the DDPMs may further include supplying a second set of noise to at least a third set of distribution information derived from the seismic information. In some examples, constructing the DDPMs may further include sampling at least the third set of distribution information.

In some examples, sampling at least the first set of distribution information is based on a first time step value. In some examples, supplying the first set of noise to at least a second set of distribution is based on the first time step value or a second time step value. In some examples, at least one of the first time step value and the second time step value are intermediate samples, the intermediate samples implemented as latent variables during the training of the neural network. In some examples, the retrieving and the outputting are performed using a network.

In some examples, the one or more DDPMs are based on image information. In some examples, the one or more DDPMs are one or more reflectivity structures.

Method 500 continues to operation 504 with one or more processors training, via a machine learning engine at the unit, a neural network based on the one or more denoising diffusion probabilistic models and an evidence lower bound. In some examples, the training engine is configured to train the neural network by inputting the one or more denoising diffusion probabilistic models. In some examples, the training engine is configured to train the neural network by comparing, to a previous output of the neural network, a current outputs of the training engine, wherein comparing is based on at least a first set of noise. In some examples, the training engine is configured to train the neural network by based on the comparing, adjusting one or more weights of the neural network. In some examples, the training engine is configured to remove the first set of noise from the neural network. In some examples, the training engine is configured to obtain a denoising object by reprioritizing a mean value of the one or more denoising diffusion probabilistic models in relation to at least the removing of the first set of noise.

Method 500 continues to operation 506 with one or more processors applying the neural network to a reflectivity profile generated using the seismic information to construct at least one refined seismic representation, wherein applying comprises. Applying may include regularizing a first iterative portion of the reflectivity profile using the neural network. Applying may include updating the reflectivity profile based on a learning rate value. Applying may include regularizing a second iterative portion of the reflectivity profile using the neural network. In some examples, regularizing the first iterative portion is based on a first loss function for the evidence lower bound and a second loss function associated with a least square migration, the least square migration based on the reflectivity profile. In some examples, applying the neural network to a reflectivity profile comprises utilizing, as a prior, a loss value for the evidence lower bound.

In one aspect, method 500, or any aspect related to it, may be performed by a system, device, apparatus, or architecture, such as the architecture 100 of FIG. 1 or system 600 of FIG. 6, which includes various components operable, configured to, or adapted to perform the method 500. System 600 is described below in further detail.

FIG. 5 is just one example of a method, and other methods including fewer, additional, or alternative operations are contemplated consistent with the disclosure.

### Example Systems

FIG. 6 illustrates a schematic diagram of an example system 600. The system 600 may be implemented as part of the enhanced regularization described with respect to FIGS. 1-5. Components of the system may be implemented at a single location or at multiple locations and may be a supervisory system or may be in communication with a supervisory system by way of a communication line. In at least one embodiment, the communication line may be a wireless communication line, a wired communication line, or both, though other types of communication line are contemplated.

The device(s) 602 may include a CPU processing system, which may be configured to perform regularization procedures, such as those described herein with respect to FIG. 1-5, as performed by the system 600. The CPU processing system of the device(s) 602 may include one or more processors 606 coupled to a computer readable medium/memory 604, for example via a bus (not shown). The one or more processors 606 and the computer readable medium/memory 604 may communicate via a message passing interface (MPI) 699. In certain aspects the computer readable medium/memory 604 is configured to store instructions (e.g., computer executable code) that when executed by the one or more processors 606, cause the one or more processors to perform the method 500 described with respect to FIG. 5, or any aspect related to it. Reference to a single processor performing a function of system 600 may include one or more processors performing that function of system 600.

In the depicted example, computer-readable medium/memory 604 stores code (e.g., executable instructions) 608 for constructing, code 610 for training, code 612 for applying, code 614 for regularizing, code 616 for updating, code 618 for sampling, code 620 for supplying, code 622 for generating, code 624 for implementing, code 626 for retrieving, code 628 for outputting, code 630 for inputting, code 632 for comparing, code 634 for adjusting, code 636 for removing, code 638 for obtaining, code 640 for (re) prioritizing, code 642 for utilizing. Processing of code 608-642 may cause the system 600 to perform the method 500 described with respect to FIG. 5, or any aspect related to it.

The one or more processors 606 include circuitry configured to implement (e.g., execute) the code stored in the computer-readable medium/memory 604, including circuitry 644 for constructing, circuitry 646 for training, circuitry 648 for applying, circuitry 650 for regularizing, circuitry 652 for updating, circuitry 654 for sampling, circuitry 656 for supplying, circuitry 658 for generating, circuitry 660 for implementing, circuitry 662 for retrieving, circuitry 664 for outputting, circuitry 666 for inputting, circuitry 668 for comparing, circuitry 670 for adjusting, circuitry 672 for removing, circuitry 674 for obtaining, circuitry 676 for (re) prioritizing, circuitry 678 for utilizing. Processing with circuitry 644-678 may cause the system 600 to perform the method 500 described with respect to FIG. 5, or any aspect related to it.

Various components of the system 600 may provide means for performing the method 500 described with respect to FIG. 5, or any aspect related to it.

The system 600 may include or be substantially coupled to a communication component 698. In the depicted example, the communication component 698 is an antenna capable of communicating with controllers similar to system 600 to perform the method 500 described with respect to FIG. 5, or any aspect related to it. In additional examples, the communication component 698 may be a bus or a wired connection.

### Example Computer System

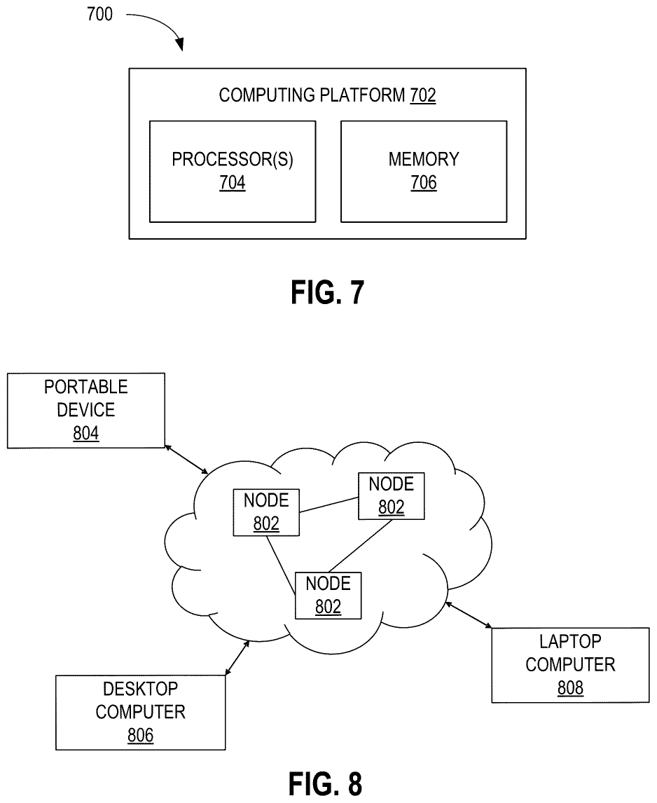

FIG. 7 is an example of a block diagram of a system 700. System 700 can be implemented using one or more modules, shown in block form in the drawings. The one or more modules can be in software or hardware form, or a combination thereof. In some examples, System 700 can be implemented as machine readable instructions for execution on one or more computing platforms 702 (referred to as a computing platform herein), as shown in FIG. 7. The computing platform 702 can include one or more computing devices selected from, for example, a desktop computer, a server, a controller, a blade, a mobile phone, a tablet, a laptop, a personal digital assistant (PDA), and the like.

The computing platform 704 can include a processor 704 and a memory 706. By way of example, the memory 706 can be implemented, for example, as a non-transitory computer storage medium, such as volatile memory (e.g., random access memory), non-volatile memory (e.g., a hard disk drive, a solid-state drive, a flash memory, or the like), or a combination thereof. The processor 704 can be implemented, for example, as one or more processor cores. The memory 706 can store machine-readable instructions that can be retrieved and executed by the processor 704 to implement system 700. Each of the processor 704 and the memory 706 can be implemented on a similar or a different computing platform. The computing platform 702 can be implemented in a cloud computing environment (for example, as disclosed herein) and thus on a cloud infrastructure. In such a situation, features of the computing platform 702 can be representative of a single instance of hardware or multiple instances of hardware executing across the multiple of instances (e.g., distributed) of hardware (e.g., computers, routers, memory, processors, or a combination thereof). Alternatively, the computing platform 702 can be implemented on a single dedicated server or workstation.

Cloud computing is a model of service delivery for enabling convenient, on-demand network access to a shared pool of configurable computing resources (e.g., networks, network bandwidth, servers, processing, memory, storage, applications, virtual machines, and services) that can be rapidly provisioned and released with minimal management effort or interaction with a provider of the service. This cloud model may include at least five characteristics, at least three service models (e.g., software as a service (SaaS, platform as a service (PaaS), and/or infrastructure as a service (IaaS)) and at least four deployment models (e.g., private cloud, community cloud, public cloud, and/or hybrid cloud). A cloud computing environment can be service orient-ed with a focus on statelessness, low coupling, modularity, and semantic interoperability.

FIG. 8 is an example of a cloud computing environment 800 that can be used for implementing one or more modules and/or systems in accordance with one or more examples, as disclosed herein. Thus, reference can be made to one or more examples of FIGS. 1-7 in the example of FIG. 8. As shown, cloud computing environment 800 can include one or more cloud computing nodes 802 with which local computing devices used by cloud consumers (or users), such as, for example, personal digital assistant (PDA), cellular, or portable device 804, a desktop computer 806, and/or a laptop computer 808, may communicate. The computing nodes 802 can communicate with one another. In some examples, the computing nodes 802 can be grouped (not shown) physically or virtually, in one or more networks, such as Private, Community, Public, or Hybrid clouds, or a combination thereof. This allows the cloud computing environment 800 to offer infrastructure, platforms and/or software as services for which a cloud consumer does not need to maintain resources on a local computing device. The devices 804-808, as shown in FIG. 8, are intended to be illustrative and that computing nodes 802 and cloud computing environment 800 can communicate with any type of computerized device over any type of network and/or network addressable connection (e.g., using a web browser). In some examples, the one or more computing nodes 802 are used for implementing one or more examples disclosed herein relating to root-source identification. Thus, in some examples, the one or more computing nodes can be used to implement modules, platforms, and/or systems, as disclosed herein.

In some examples, the cloud computing environment 800 can provide one or more functional abstraction layers. It is to be understood that the cloud computing environment 800 need not provide all of the one or more functional abstraction layers (and corresponding functions and/or components), as disclosed herein. For example, the cloud computing environment 800 can provide a hardware and software layer that can include hardware and software components. Examples of hardware components include: mainframes; RISC (Reduced Instruction Set Computer) architecture based servers; servers; blade servers; storage devices; and networks and networking components. In some embodiments, software components include network application server software and database software.

In some examples, the cloud computing environment 800 can provide a virtualization layer that provides an abstraction layer from which the following examples of virtual entities may be pro-vided: virtual servers; virtual storage; virtual networks, including virtual private networks; virtual applications and operating systems; and virtual clients. In some examples, the cloud computing environment 800 can provide a management layer that can provide the functions described be-low. For example, the management layer can provide resource provisioning that can provide dynamic procurement of computing resources and other resources that are utilized to perform tasks within the cloud computing environment. The management layer can also provide metering and pricing to provide cost tracking as resources are utilized within the cloud computing environment 800, and billing or invoicing for consumption of these resources. In one example, these re-sources may include application software licenses. Security provides identity verification for cloud consumers and tasks, as well as protection for data and other resources. The management layer can also provide a user portal that provides access to the cloud computing environment 800 for consumers and system administrators. The management layer can also provide service level management, which can provide cloud computing resource allocation and management such that required service levels are met. Service Level Agreement (SLA) planning and fulfillment can also be provided to provide pre-arrangement for, and procurement of, cloud computing re-sources for which a future requirement is anticipated in accordance with an SLA.

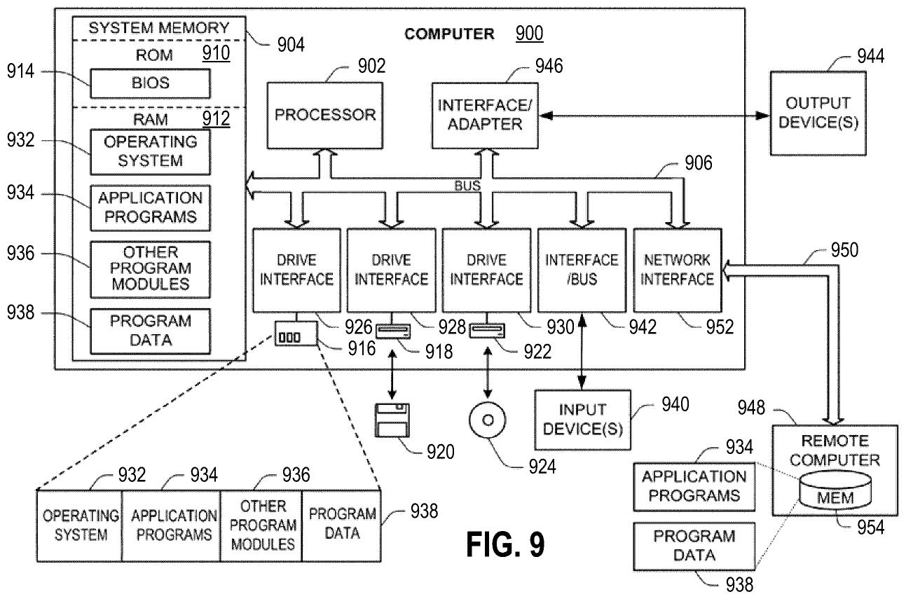

In view of the foregoing structural and functional description, those skilled in the art will appreciate that portions of the embodiments may be embodied as a method, data processing system, or computer program product. Accordingly, these portions of the present embodiments may take the form of an entirely hardware embodiment, an entirely software embodiment, or an embodiment combining software and hardware, such as shown and described with respect to the computer system of FIG. 9. Furthermore, portions of the embodiments may be a computer program product on a computer-readable storage medium having computer readable program code on the medium. Any non-transitory, tangible storage media possessing structure may be utilized including, but not limited to, static and dynamic storage devices, volatile and non-volatile memories, hard disks, optical storage devices, and magnetic storage devices, but excludes any medium that is not eligible for patent protection under 35 U.S.C. § 101 (such as a propagating electrical or electromagnetic signals per se). As an example and not by way of limitation, computer-readable storage media may include a semiconductor-based circuit or device or other IC (such, as for example, a field-programmable gate array (FPGA) or an ASIC), a hard disk, an HDD, a hybrid hard drive (HHD), an optical disc, an optical disc drive (ODD), a magneto-optical disc, a magneto-optical drive, a floppy disk, a floppy disk drive (FDD), magnetic tape, a holographic storage medium, a solid-state drive (SSD), a RAM-drive, a SECURE DIGITAL card, a SECURE DIGITAL drive, or another suitable computer-readable storage medium or a combination of two or more of these, where appropriate. A computer-readable non-transitory storage medium may be volatile, nonvolatile, or a combination of volatile and non-volatile, as ap-propriate.

Certain embodiments have also been described herein with reference to block illustrations of methods, systems, and computer program products. It will be understood that blocks and/or combinations of blocks in the illustrations, as well as methods or steps or acts or processes de-scribed herein, can be implemented by a computer program comprising a routine of set instructions stored in a machine-readable storage medium as described herein. These instructions may be provided to one or more processors of a general purpose computer, special purpose computer, or other programmable data processing apparatus (or a combination of devices and circuits) to pro-duce a machine, such that the instructions of the machine, when executed by the processor, implement the functions specified in the block or blocks, or in the acts, steps, methods and process-es described herein.

These processor-executable instructions may also be stored in computer-readable memory that can direct a computer or other programmable data processing apparatus to function in a particular manner, such that the instructions stored in the computer-readable memory result in an article of manufacture including instructions which implement the function specified. The computer program instructions may also be loaded onto a computer or other programmable data processing apparatus to cause a series of operational steps to be performed on the computer or other programmable apparatus to realize a computer implemented process such that the instructions which execute on the computer or other programmable apparatus provide steps for implementing the functions specified in flowchart blocks that may be described herein.

In this regard, FIG. 9 illustrates one example of a computer system 900 that can be employed to execute one or more embodiments of the present disclosure. Computer system 900 can be implemented on one or more general purpose networked computer systems, embedded computer systems, routers, switches, server devices, client devices, various intermediate devices/nodes or standalone computer systems. Additionally, computer system 900 can be implemented on various mobile clients such as, for example, a personal digital assistant (PDA), laptop computer, pager, and the like, provided it includes sufficient processing capabilities.

Computer system 900 includes processing unit 902, system memory 904, and system bus 906 that couples various system components, including the system memory 904, to processing unit 902. System memory 904 can include volatile (e.g. RAM, DRAM, SDRAM, Double Data Rate (DDR) RAM, etc.) and non-volatile (e.g. Flash, NAND, etc.) memory. Dual microprocessors and other multi-processor architectures also can be used as processing unit 902. System bus 906 may be any of several types of bus structure including a memory bus or memory controller, a peripheral bus, and a local bus using any of a variety of bus architectures. System memory 904 includes read only memory (ROM) 910 and random access memory (RAM) 912. A basic input/output system (BIOS) 914 can reside in ROM 910 containing the basic routines that help to transfer information among elements within computer system 900.

Computer system 900 can include a hard disk drive 916, magnetic disk drive 918, e.g., to read from or write to removable disk 920, and an optical disk drive 922, e.g., for reading CD-ROM disk 924 or to read from or write to other optical media. Hard disk drive 916, magnetic disk drive 918, and optical disk drive 922 are connected to system bus 906 by a hard disk drive interface 926, a magnetic disk drive interface 928, and an optical drive interface 930, respectively. The drives and associated computer-readable media provide nonvolatile storage of data, data structures, and computer-executable instructions for computer system 900. Although the description of computer-readable media above refers to a hard disk, a removable magnetic disk and a CD, other types of media that are readable by a computer, such as magnetic cassettes, flash memory cards, digital video disks and the like, in a variety of forms, may also be used in the operating environment; further, any such media may contain computer-executable instructions for implementing one or more parts of embodiments shown and described herein.

Computer system 900 may operate in a networked environment using logical connections to one or more remote computers, such as remote computer 948. Remote computer 948 may be a workstation, computer system, router, peer device, or other common network node, and typically includes many or all the elements described relative to computer system 900. The logical connections, schematically indicated at 950, can include a local area network (LAN) and/or a wide area network (WAN), or a combination of these, and can be in a cloud-type architecture, for example configured as private clouds, public clouds, hybrid clouds, and multi-clouds. When used in a LAN networking environment, computer system 900 can be connected to the local network through a network interface or adapter 952. When used in a WAN networking environment, computer system 900 can include a modem, or can be connected to a communications server on the LAN. The modem, which may be internal or external, can be connected to system bus 906 via an appropriate port interface. In a networked environment, application programs 934 or program data 938 depicted relative to computer system 900, or portions thereof, may be stored in a remote memory storage device 954.

Although this disclosure includes a detailed description on a computing platform and/or computer, implementation of the teachings recited herein are not limited to only such computing platforms. Rather, embodiments of the present disclosure are capable of being implemented in conjunction with any other type of computing environment now known or later developed.

Cloud computing is a model of service delivery for enabling convenient, on-demand network access to a shared pool of configurable computing resources (e.g., networks, network bandwidth, servers, processing, memory, storage, applications, virtual machines, and services) that can be rap-idly provisioned and released with minimal management effort or interaction with a provider of the service. This cloud model may include at least five characteristics, at least three service models (e.g., software as a service (Saas, platform as a service (PaaS), and/or infrastructure as a ser-vice (IaaS)) and at least four deployment models (e.g., private cloud, community cloud, public cloud, and/or hybrid cloud). A cloud computing environment can be service oriented with a focus on statelessness, low coupling, modularity, and semantic interoperability.

### Example Aspects

Implementation examples are described in the following numbered clauses:

Aspect 1: A system for seismic processing, including: a memory; and one or more processors and coupled to the memory, the memory having computer-readable code stored thereon configured to cause the one or more processors to perform: constructing, via the one or more processors, one or more denoising diffusion probabilistic models based on seismic information; training, via a machine learning engine at the unit, a neural network based on the one or more denoising diffusion probabilistic models and an evidence lower bound; and applying the neural network to a reflectivity profile generated using the seismic information to construct at least one refined seismic representation, wherein applying includes: regularizing a first iterative portion of the reflectivity profile using the neural network; updating the reflectivity profile based on a learning rate value; and regularizing a second iterative portion of the reflectivity profile using the neural network.

Aspect 2: The system of aspect 1, wherein constructing the one or more denoising diffusion probabilistic models includes: sampling at least a first set of distribution information derived from the seismic information; supplying a first set of noise to at least a second set of distribution information derived from the seismic information; and sampling at least the second set of distribution information.

Aspect 3: The system of aspect 2, wherein constructing further includes: supplying a second set of noise to at least a third set of distribution information derived from the seismic information; and sampling at least the third set of distribution information.

Aspect 4: The system of any one of aspects 2 and 3, wherein: sampling at least the first set of distribution information is based on a first time step value; and supplying the first set of noise to at least a second set of distribution is based on the first time step value or a second time step value.

Aspect 5: The system of aspect 4, wherein at least one of the first time step value and the second time step value are intermediate samples, the intermediate samples implemented as latent variables during the training of the neural network.

Aspect 6: The system of any one of aspects 1 through 5, wherein the memory having the computer-readable code stored thereon is further configured to cause the one or more processors to perform: retrieving, from a database, the seismic information, the seismic information collected over time at a targeted rock formation; and outputting the at least one refined seismic representation to an output device.

Aspect 7: The system of aspect 6, wherein the retrieving and the outputting are performed using a network.

Aspect 8: The system of any one of aspects 1 through 7, wherein the one or more denoising diffusion probabilistic models is based on image information.

Aspect 9: The system of aspect 8, wherein the one or more denoising diffusion probabilistic models is a reflectivity structure.

Aspect 10: The system of any one of aspects 1 through 9, wherein the machine learning engine includes a training engine configured to train the neural network and an inference engine configured to apply the neural network to the reflectivity profile.

Aspect 11: The system of aspect 10, wherein the training engine is configured to train the neural network by: inputting the one or more denoising diffusion probabilistic models; comparing, to a previous output of the neural network, a current outputs of the training engine, wherein comparing is based on at least a first set of noise; and based on the comparing, adjusting one or more weights of the neural network.

Aspect 12: The system of aspect 11, wherein the training engine is configured to remove the first set of noise from the neural network.

Aspect 13: The system of aspect 12, wherein the training engine is configured to obtain a denoising object by reprioritizing a mean value of the one or more denoising diffusion probabilistic models in relation to at least the removing of the first set of noise.

Aspect 14: The system of any one of aspects 1 through 13, wherein regularizing the first iterative portion is based on a first loss function for the evidence lower bound and a second loss function associated with a least square migration, the least square migration based on the reflectivity profile.

Aspect 15: The system of any one of aspects 1 through 14, wherein applying the neural network to a reflectivity profile includes utilizing, as a prior, a loss value for the evidence lower bound.

Aspect 16: A method for seismic processing, including: constructing, via one or more processors, one or more denoising diffusion probabilistic models based on seismic information; training, via a machine learning engine, a neural network based on the one or more denoising diffusion probabilistic models and an evidence lower bound; and applying the neural network to a reflectivity profile generated using the seismic information to construct at least one refined seismic representation, wherein applying includes: regularizing a first iterative portion of the reflectivity profile using the neural network; updating the reflectivity profile based on a learning rate value; and regularizing a second iterative portion of the reflectivity profile using the neural network.

Aspect 17: The method of aspect 16, wherein constructing includes: sampling at least a first set of distribution information derived from the seismic information; supplying a first set of noise to at least a second set of distribution information derived from the seismic information; and sampling at least the second set of distribution information.

Aspect 18: The method of aspect 17, wherein the first set of noise is Gaussian noise.

Aspect 19: The method of any one of aspects 16 through 18, wherein the machine learning engine includes a training engine configured to train the neural network and an inference engine configured to apply the neural network to the reflectivity profile.

Aspect 20: The method of aspect 19, wherein the training engine is configured to train the neural network by: inputting the one or more denoising diffusion probabilistic models; comparing, to a previous output of the neural network, a current outputs of the training engine, wherein comparing is based on at least a first set of noise; and based on the comparing, adjusting one or more weights of the neural network.

Aspect 21: An apparatus or device including a memory comprising executable instructions, and a processor configured to execute the executable instructions and cause the apparatus to perform a method in accordance with any one of aspects 1-20.

Aspect 22: An apparatus or device, including means for performing a method in accordance with any one of aspects 1-20.

Aspect 23: A non-transitory computer-readable medium including executable instructions that, when executed by a processor of an apparatus, cause the apparatus to perform a method in accordance with any one of aspects 1-20.

Aspect 24: A computer program product embodied on a computer-readable storage medium comprising code for performing a method in accordance with any one of aspects 1-20.

### Additional Considerations

Although this disclosure includes a detailed description on a computing platform and/or computer, implementation of the teachings recited herein are not limited to only such computing platforms. Rather, embodiments of the present disclosure are capable of being implemented in conjunction with any other type of computing environment now known or later developed.

The present disclosure may be a system, a method, and/or a computer program product at any possible technical detail level of integration. The computer program product may include a computer readable storage medium (or media) having computer readable program instructions thereon for causing a processor to conduct aspects of the present disclosure. The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present disclosure may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware based systems that perform the specified functions or acts or conduct combinations of special purpose hardware and computer instructions.

“Real-time” may refer to the capability of a system or process to respond to inputs or events within a strict period of time, such as immediately or within seconds or milliseconds. In computing and information technology, real-time systems may be designed to process data and provide outputs instantaneously or almost instantaneously, ensuring minimal latency.

The terminology used herein is for the purpose of describing particular embodiments only and is not intended to be limiting of the disclosure. As used herein, for example, the singular forms “a,” “an,” and “the” are intended to include the plural forms as well, unless the context clearly indicates otherwise. It will be further understood that the terms “contains”, “containing”, “includes”, “including,” “comprises”, and/or “comprising,” and variations thereof, when used in this specification, specify the presence of stated features, integers, steps, operations, elements, and/or components, but do not preclude the presence or addition of one or more other features, integers, steps, operations, elements, components, and/or groups thereof.

Terms of orientation used herein are merely for purposes of convention and referencing and are not to be construed as limiting. However, it is recognized these terms could be used with reference to an operator or user. Accordingly, no limitations are implied or to be inferred. In addition, the use of ordinal numbers (e.g., first, second, third, etc.) is for distinction and not counting. For example, the use of “third” does not imply there must be a corresponding “first” or “second.” Also, if used herein, the terms “coupled” or “coupled to” or “connected” or “connected to” or “attached” or “attached to” may indicate establishing either a direct or indirect connection and is not limited to either unless expressly referenced as such. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim. The term “based on” means “based at least in part on.” The terms “about” and “approximately” can be used to include any numerical value that can vary without changing the basic function of that value. When used with a range, “about” and “approximately” also disclose the range defined by the absolute values of the two endpoints, e.g., “about 2 to about 4” also discloses the range “from 2 to 4.” Generally, the terms “about” and “approximately” may refer to plus or minus 5-10% of the indicated number.

While the disclosure has described several exemplary embodiments, it will be understood by those skilled in the art that various changes can be made, and equivalents can be substituted for elements thereof, without departing from the spirit and scope of the disclosure. In addition, many modifications will be appreciated by those skilled in the art to adapt a particular instrument, situation, or material to embodiments of the disclosure without departing from the essential scope thereof. Therefore, it is intended that the disclosure not be limited to the particular embodiments disclosed, or to the best mode contemplated for conducting this disclosure, but that the disclosure will include all embodiments falling within the scope of the appended claims. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

What is claimed is:

1. A system for seismic processing, comprising:
a memory; and
one or more processors and coupled to the memory, the memory having computer-readable code stored thereon configured to cause the one or more processors to perform:
constructing, via the one or more processors, one or more denoising diffusion probabilistic models based on seismic information;
training, via a machine learning engine at the unit, a neural network based on the one or more denoising diffusion probabilistic models and an evidence lower bound; and
applying the neural network to a reflectivity profile constructed using the seismic information to construct at least one refined seismic representation, wherein applying comprises:
regularizing a first iterative portion of the reflectivity profile using the neural network;
updating the reflectivity profile based on a learning rate value; and
regularizing a second iterative portion of the reflectivity profile using the neural network.

2. The system of claim 1, wherein constructing the one or more denoising diffusion probabilistic models comprises:
sampling at least a first set of distribution information derived from the seismic information;
supplying a first set of noise to at least a second set of distribution information derived from the seismic information; and
sampling at least the second set of distribution information.

3. The system of claim 2, wherein constructing further comprises:
supplying a second set of noise to at least a third set of distribution information derived from the seismic information; and
sampling at least the third set of distribution information.

4. The system of claim 2, wherein:
sampling at least the first set of distribution information is based on a first time step value; and
supplying the first set of noise to at least a second set of distribution is based on the first time step value or a second time step value.

5. The system of claim 4, wherein at least one of the first time step value and the second time step value are intermediate samples, the intermediate samples implemented as latent variables during the training of the neural network.

6. The system of claim 1, wherein the memory having the computer-readable code stored thereon is further configured to cause the one or more processors to perform:
retrieving, from a database, the seismic information, the seismic information collected over time at a targeted rock formation; and
outputting the at least one refined seismic representation to an output device.

7. The system of claim 6, wherein the retrieving and the outputting are performed using a network.

8. The system of claim 1, wherein the one or more denoising diffusion probabilistic models are based on image information.

9. The system of claim 8, wherein the one or more denoising diffusion probabilistic models are one or more reflectivity structures.

10. The system of claim 1, wherein the machine learning engine comprises a training engine configured to train the neural network and an inference engine configured to apply the neural network to the reflectivity profile.

11. The system of claim 10, wherein the training engine is configured to train the neural network by:
inputting the one or more denoising diffusion probabilistic models;
comparing, to a previous output of the neural network, a current outputs of the training engine, wherein comparing is based on at least a first set of noise; and
based on the comparing, adjusting one or more weights of the neural network.

12. The system of claim 11, wherein the training engine is configured to remove the first set of noise from the neural network.

13. The system of claim 12, wherein the training engine is configured to obtain a denoising object by reprioritizing a mean value of the one or more denoising diffusion probabilistic models in relation to at least the removing of the first set of noise.

14. The system of claim 1, wherein regularizing the first iterative portion is based on a first loss function for the evidence lower bound and a second loss function associated with a least square migration, the least square migration based on the reflectivity profile.

15. The system of claim 1, wherein applying the neural network to a reflectivity profile comprises utilizing, as a prior, a loss value for the evidence lower bound.

16. A method for seismic processing, comprising:
constructing, via one or more processors, one or more denoising diffusion probabilistic models based on seismic information;
training, via a machine learning engine, a neural network based on the one or more denoising diffusion probabilistic models and an evidence lower bound; and
applying the neural network to a reflectivity profile generated using the seismic information to construct at least one refined seismic representation, wherein applying comprises:
regularizing a first iterative portion of the reflectivity profile using the neural network;
updating the reflectivity profile based on a learning rate value; and
regularizing a second iterative portion of the reflectivity profile using the neural network.

17. The method of claim 16, wherein constructing comprises:
sampling at least a first set of distribution information derived from the seismic information;
supplying a first set of noise to at least a second set of distribution information derived from the seismic information; and
sampling at least the second set of distribution information.

18. The method of claim 17, wherein the first set of noise is Gaussian noise.

19. The method of claim 16, wherein the machine learning engine comprises a training engine configured to train the neural network and an inference engine configured to apply the neural network to the reflectivity profile.

20. The method of claim 19, wherein the training engine is configured to train the neural network by:
inputting the one or more denoising diffusion probabilistic models;
comparing, to a previous output of the neural network, a current outputs of the training engine, wherein comparing is based on at least a first set of noise; and
based on the comparing, adjusting one or more weights of the neural network.
